(19) United States
(12) Patent Application Publication
(10) Pub. No.: US 2025/0205827 A1
(43) Pub. Date: Jun. 26, 2025

(54) SUBSTRATE PROCESSING APPARATUS AND SUBSTRATE PROCESSING METHOD

(71) Applicant: Tokyo Electron Limited, Tokyo (JP)

(72) Inventors: Yohei YAMASHITA, Kikuchi-gun, Kumamoto (JP); Yohei YAMAWAKI, Kikuchi-gun, Kumamoto (JP)

(73) Assignee: Tokyo Electron Limited, Tokyo (JP)

(21) Appl. No.: 18/847,378

(22) PCT Filed: Mar. 3, 2023
(86) PCT No.: PCT/JP2023/008109

§ 371 Date: Sep. 16, 2024

(30) Foreign Application Priority Data
Mar. 17, 2022 (JP) 2022-042770
Dec. 14, 2022 (JP) 2022-199749

(51) Int. Cl. B23K 26/70; B23K 26/03; B23K 26/042; B23K 26/08; B23K 26/12; B23K 26/16; B23K 26/50; B23K 101/40

(52) U.S. Cl. CPC B23K 26/706; B23K 26/032; B23K 26/042; B23K 26/0823; B23K 26/083; B23K 26/123; B23K 26/16; B23K 26/50; B23K 2101/40

(57) ABSTRACT

A substrate processing apparatus of processing a substrate includes a substrate holder having a holding surface on which the substrate is held; a rotator configured to rotate the substrate on the holding surface around a rotation axis of the substrate holder; and a laser radiator configured to radiate laser light to the substrate on the holding surface. The holding surface of the substrate holder has a diameter smaller than that of the substrate.

### TECHNICAL FIELD

The various aspects and embodiments described herein pertain generally to a substrate processing apparatus and a substrate processing method.

### BACKGROUND

Patent Document 1 describes a substrate processing method in which laser light is radiated in a pulse shape to a laser absorption layer of a combined substrate. In this substrate processing method, the laser light is radiated toward a central portion of the laser absorption layer from an outer periphery thereof.

### PRIOR ART DOCUMENT

Patent Document 1: International Publication No. 2021/131711

### DISCLOSURE OF THE INVENTION

### Problems to be Solved by the Invention

Exemplary embodiments provide a technique capable of suppressing damage to a substrate holding surface due to laser light when processing a substrate on the substrate holding surface by radiating the laser light to the substrate.

### Means for Solving the Problems

In an exemplary embodiment, a substrate processing apparatus of processing a substrate includes a substrate holder having a holding surface on which the substrate is held; a rotator configured to rotate the substrate on the holding surface around a rotation axis of the substrate holder; and a laser radiator configured to radiate laser light to the substrate on the holding surface. The holding surface of the substrate holder has a diameter smaller than that of the substrate.

### Effect of the Invention

According to the exemplary embodiment, it is possible to suppress damage to the substrate holding surface due to the laser light when processing the substrate on the substrate holding surface by radiating the laser light to the substrate.

### BRIEF DESCRIPTION OF THE DRAWINGS

FIG. 1 is a side view schematically illustrating a structure of a combined wafer to be processed.

FIG. 2 is a side view schematically illustrating a configuration of a wafer processing system.

FIG. 3 is a side view schematically illustrating a configuration of a wafer processing apparatus according to a first exemplary embodiment.

FIG. 4 is a plan view schematically illustrating the configuration of the wafer processing apparatus according to the first exemplary embodiment.

FIG. 5 is an explanatory diagram illustrating the combined wafer attracted to and held on a chuck.

FIG. 6 is a side view illustrating another configuration example of the chuck belonging to the wafer processing apparatus.

FIG. 7 is a side view illustrating still another configuration example of the chuck belonging to the wafer processing apparatus.

FIG. 8 is a side view illustrating yet another configuration example of the chuck belonging to the wafer processing apparatus.

FIG. 9 is a side view illustrating another configuration example of a wafer drop prevention pin.

FIG. 10 is a side view illustrating still another configuration example of the wafer drop prevention pin.

FIG. 11 is an explanatory diagram illustrating a state in which laser light is radiated to a laser absorption layer.

FIG. 12A and FIG. 12B are explanatory diagrams illustrating a state in which a first wafer is separated from the laser absorption layer.

FIG. 13 is an explanatory diagram illustrating an example of radiation of laser light to the laser absorption layer.

FIG. 14A and FIG. 14B are explanatory diagrams illustrating a conventional method of determining a radiation position of laser light.

FIG. 15A and FIG. 15B are explanatory diagrams illustrating a method of determining a radiation position of laser light according to the exemplary embodiment.

FIG. 16 is an explanatory diagram illustrating the method of determining the radiation position of the laser light according to the exemplary embodiment.

FIG. 17 is an explanatory diagram illustrating another example of the radiation of the laser light to the laser absorption layer.

FIG. 18 is a plan view schematically illustrating a configuration of a wafer processing apparatus according to a second exemplary embodiment.

FIG. 19 is a front view schematically illustrating the configuration of the wafer processing apparatus according to the second exemplary embodiment.

FIG. 20 is an explanatory diagram illustrating reflection of laser light in a beam damper.

FIG. 21 is an explanatory diagram illustrating a gas exhaust by a dust collector.

### DETAILED DESCRIPTION

In a manufacturing process for a semiconductor device, in a combined wafer in which two sheets of semiconductor substrates (hereinafter, referred to as “wafers”) are bonded to each other, a device layer formed on a front surface of a first wafer is transferred to a second wafer. This transfer of the device layer is performed by using, for example, laser lift-off. That is, laser light is radiated to a laser absorption layer formed between the first wafer and the device layer, and the first wafer and the laser absorption layer are separated, thereby transferring the device layer to the second wafer.

In the laser lift-off, the laser light is radiated in a pulse shape while rotating the combined wafer held on a substrate holder and moving the laser light relative to the combined wafer in a radial direction.

At this time, if the combined wafer is held eccentrically with respect to the substrate holder, that is, if there is a misalignment between a rotation center of the substrate holder and a center of the combined wafer, the distance between the rotation center of the substrate holder and an outer end of the combined wafer varies in a circumferential direction. Therefore, if a laser light radiation position is set at the position of the outer end of the combined wafer, there is a risk that the laser light may be radiated to a radially outside of the outer end of the combined wafer in the circumferential direction when the laser light is radiated while rotating the combined wafer. Further, at this time, if a size of a substrate holding surface of the substrate holder is equal to or larger than the size of the combined wafer, there is a risk that the laser light may be radiated to the substrate holding surface of the substrate holder, causing damage to the substrate holding surface. Furthermore, once the substrate holding surface is damaged in this way, there is a risk that the next combined wafer held by the substrate holder may be also damaged, that the holding of the combined wafer by the substrate holder may be adversely affected, or that a top surface height position of the combined wafer on the substrate holder may change, causing a processing defect.

In view of the foregoing, the present disclosure provides technique capable of suppressing the substrate holding surface from being damaged by the laser light when processing the substrate by radiating the laser light to the substrate on the substrate holding surface. Hereinafter, a wafer processing system having a wafer processing apparatus as a substrate processing apparatus and a wafer processing method as a substrate processing method according to an exemplary embodiment will be described with reference to the accompanying drawings. In the present specification and the drawings, parts having substantially the same functions and configurations will be assigned same reference numerals, and redundant description thereof will be omitted.

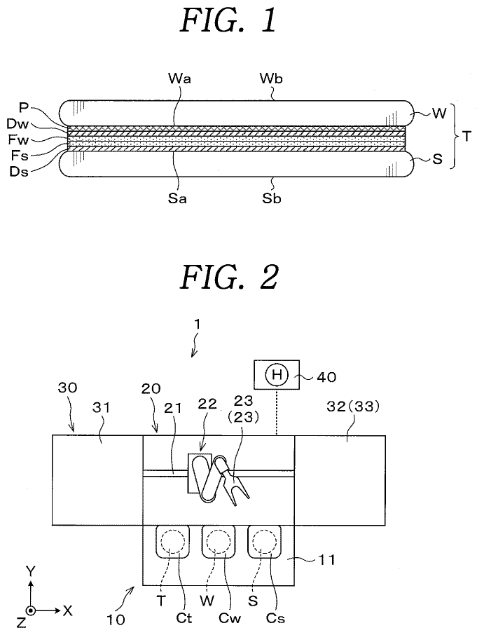

In a wafer processing system 1 to be described below according to the present exemplary embodiment, a processing is performed on a combined wafer T as a substrate in which a first wafer W and a second wafer S are bonded, as shown in FIG. 1. Hereinafter, in the first wafer W, a surface bonded to the second wafer S will be referred to as a front surface Wa, and a surface opposite to the front surface Wa will be referred to as a rear surface Wb. Likewise, in the second wafer S, a surface bonded to the first wafer W will be referred to as a front surface Sa, and a surface opposite to the front surface Sa will be referred to as a rear surface Sb.

The first wafer W is a semiconductor wafer such as, but not limited to, a silicon substrate. In the exemplary embodiment, the first wafer W has a substantially circular plate shape. On the front surface Wa of the first wafer W, a laser absorption layer P, a device layer Dw, and a surface film Fw are stacked in this order from the front surface Wa side. The laser absorption layer P absorbs laser light radiated from a laser radiation device 110, as will be described later. An oxide film (SiO₂ film), for example, is used as the laser absorption layer P, but the laser absorption layer is not particularly limited as long as it is capable of absorbing the laser light. The device layer Dw includes a plurality of devices. The surface film Fw may be, by way of example, an oxide film (THOX film, SiO₂ film or a TEOS film), a SiC film, a SiCN film, or an adhesive. Further, the position of the laser absorption layer P is not limited to the example of the above-described exemplary embodiment, and the laser absorption layer P may be formed between the device layer Dw and the surface film Fw, for example. In addition, the device layer Dw and the surface film Fw may not be formed on the front surface Wa. In this case, the laser absorption layer P is formed on the second wafer S side, and a device layer Ds on the second wafer S to be described later is transferred to the first wafer W.

The second wafer S is a semiconductor wafer such as, but not limited to, a silicon substrate. In the present exemplary embodiment, the second wafer S has a substantially circular plate shape. On the front surface Sa of the second wafer S, a device layer Ds and a surface film Fs are stacked in this order from the front surface Sa side. The device layer Ds and the surface film Fs are the same as the device layer Dw and the surface film Fw of the first wafer W, respectively. The surface film Fw of the first wafer W and the surface film Fs of the second wafer S are bonded. Further, the device layer Ds and the surface film Fs may not be formed on the front surface Sa.

As depicted in FIG. 2, the wafer processing system 1 has a configuration in which a carry-in/out block 10, a transfer block 20 and a processing block 30 are connected as one body. The carry-in/out block 10 and the processing block 30 are disposed around the transfer block 20. Specifically, the carry-in/out block 10 is disposed on the negative Y-axis side of the transfer block 20. A wafer processing apparatus 31 of the processing block 30 to be described later is disposed on the negative X-axis side of the transfer block 20, and a cleaning apparatus 32 to be described later and an inverting apparatus 33 to be described later are disposed on the positive X-axis side of the transfer block 20.

In the carry-in/out block 10, cassettes Ct, Cw, and Cs capable of accommodating a plurality of combined wafers T, a plurality of first wafers W and a plurality of second wafers S, respectively, are carried to/from the outside, for example. The carry-in/out block 10 is provided with a cassette placement table 11. In the shown example, a plurality of, for example, the three cassettes Ct, Cw, and Cs can be disposed on the cassette placement table 11 in a row in the X-axis direction. Here, the number of the cassettes Ct, Cw, and Cs placed on the cassette placement table 11 is not limited to the example of the present exemplary embodiment, but can be selected as required.

The transfer block 20 is provided with a wafer transfer device 22 configured to be movable on a transfer path 21 extending in the X-axis direction. The wafer transfer device 22 has, for example, two transfer arms 23 each configured to hold and transfer the combined wafer T, the first wafer W, or the second wafer S. Each transfer arm 23 is configured to be movable in a horizontal direction and a vertical direction and pivotable around a horizontal axis and a vertical axis. Further, the configuration of the transfer arm 23 is not limited to the example of the present exemplary embodiment, and may have any of various configurations. Moreover, the wafer transfer device 22 is configured to be able to transfer the combined wafer T, the first wafer W, and the second wafer S to/from the cassettes Ct, Cw, and Cs of the cassette placement table 11, the wafer processing apparatus 31 to be described later, the cleaning apparatus 32 to be described later and the inverting apparatus 33 to be described later.

The processing block 30 has the wafer processing apparatus 31, the cleaning apparatus 32, and the inverting apparatus 33. In one example, the cleaning apparatus 32 and the inverting apparatus 33 are stacked on top of each other on the positive X-axis side of the transfer block 20.

The wafer processing apparatus 31 radiates laser light to the laser absorption layer P of the first wafer W to reduce bonding strength at an interface between the first wafer W and the laser absorption layer P, and then separates the first wafer W from the second wafer S starting from the interface. The configuration of the wafer processing apparatus 31 will be discussed later.

The cleaning apparatus 32 cleans a surface of the laser absorption layer P formed on the front surface Sa of the second wafer S separated in the wafer processing apparatus 31. For example, a brush is brought into contact with the surface of the laser absorption layer P to scrub-clean it. Further, a pressurized cleaning liquid may be used for the cleaning of the surface. In addition, the cleaning apparatus 32 may be configured to clean the rear surface Sb of the second wafer S as well as the front surface Sa thereof.

The inverting apparatus 33 is configured to invert the front and rear surfaces of the first wafer W separated from the second wafer S in the wafer processing apparatus 31. Here, the configuration of the inverting apparatus 33 is not particularly limited.

The above-described wafer processing system 1 is provided with a control device 40 as a controller. The control device 40 is, for example, a computer, and has a program storage (not shown). The program storage stores a program for controlling the processes on the combined wafer T in the wafer processing system 1. Furthermore, the program storage also stores a program for executing the processes on the wafer W in the wafer processing system 1 by controlling the operations of a driving system, such as the above-described various processing apparatuses and transfer devices. In addition, the program is recorded on a computer-readable recording medium H, and may be installed from the recording medium H into the control device 40. Further, the recording medium H may be transitory or non-transitory.

Further, in the above-described present exemplary embodiment, the first wafer W is separated from the second wafer S in the wafer processing apparatus 31. In the wafer processing system 1, however, a separating device (not shown) configured to separate the first wafer W from the second wafer S may be independently provided.

Now, the aforementioned wafer processing apparatus 31 will be explained.

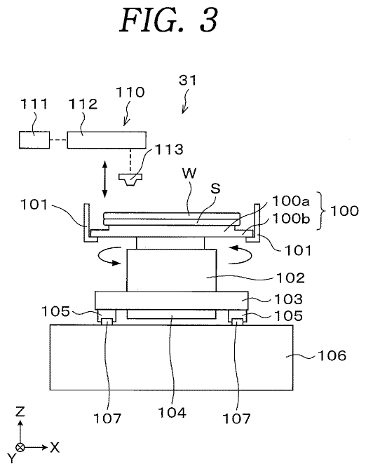

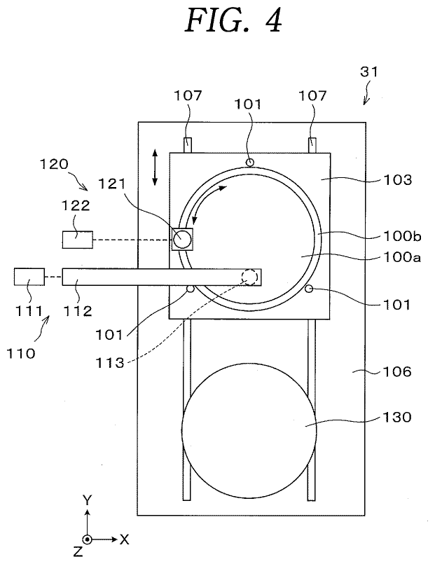

As illustrated in FIG. 3 and FIG. 4, the wafer processing apparatus 31 has a chuck 100 configured to hold the combined wafer T on a top surface thereof. The chuck 100 has a substrate holder 100a and a light shield 100b. The height of a top surface of the light shield 100b is set to be lower than the height of a top surface of the substrate holder 100a, that is, the chuck 100 has an upwardly protruding shape in a cross sectional view.

The substrate holder 100a has a substrate holding surface on the top surface thereof. The substrate holding surface is formed to have a diameter smaller than that of the combined wafer T held by the substrate holder 100a, desirably, to have an appropriate size in consideration of transfer accuracy of the combined wafer T. More specifically, the substrate holder 100a is configured so that the combined wafer T can be held on the entire surface thereof even when the combined wafer T is placed eccentrically due to a factor such as transfer accuracy or the like. Further, the substrate holder 100a attracts and holds a part of a radially inner side of the rear surface Sb of the second wafer S. In other words, on the substrate holder 100a, an outer edge portion of the combined wafer T is in a floating state above the light shield 100b. The substrate holder 100a is, by way of non-limiting example, an electrostatic chuck (ESC) or a vacuum chuck.

The light shield 100b is disposed to surround the substrate holder 100a when viewed from the top. The light shield 100b is made of a material that is not transmissive to the laser light radiated from the laser radiation device 110 to be described later, such as ceramic or a metal material, and is configured to receive the laser light, which is radiated from the laser radiation device 110 and passes through a radially outer side of the combined wafer T on the substrate holder 100a, thereby suppressing the laser light L from reaching below the chuck 100.

Further, the chuck 100 is provided with a plurality of, for example, three wafer drop prevention pins 101 so as to surround the substrate holder 100a along a radial direction, more specifically, so as to surround the combined wafer T on the substrate holder 100a. The wafer drop prevention pins 101 suppress the first wafer W after being subjected to the radiation of the laser light L to the laser absorption layer Pas will be described later from falling down from the chuck 100 by, for example, a centrifugal force accompanying rotation of the chuck 100 or an inertial force accompanying movement of the chuck 100. The wafer drop prevention pins 101 are fixed to, for example, a bottom surface side of the light shield 100b, and configured to be rotatable as one body with the chuck 100 by a rotating mechanism 104 to be described later and, also, movable as one body with the chuck 100 in the Y-axis direction by a moving mechanism 105.

The chuck 100 is supported on a slider table 103 as a stage with an air bearing 102 therebetween. The rotating mechanism 104 is provided on the bottom surface of the slider table 103. The rotating mechanism 104 has, for example, a motor as a driving source embedded therein. The chuck 100 is configured to be rotatable around a 0-axis (vertical axis) via the air bearing 102 by the rotating mechanism 104. The slider table 103 is configured to be movable along a rail 107 provided on a base 106 and extending in the Y-axis direction by the moving mechanism 105 provided on the bottom surface thereof. Here, although a driving source of the moving mechanism 105 is not particularly limited, a linear motor, for example, may be used.

The laser radiation device 110 is provided above the chuck 100. The laser radiation device 110 has a laser head 111, an optical system 112, and a lens 113.

The laser head 111 has a laser oscillator (not shown) that oscillates the laser light L (see FIG. 11) in a pulse shape. This laser light L is a so-called pulse laser. Also, in this exemplary embodiment, the laser light L is CO₂ laser light, and this CO₂ laser light has a wavelength of, e.g., 8.9 μm to 11 μm. In addition, the laser head 111 may have, besides the laser oscillator, other devices such as, but not limited to, an amplifier.

The optical system 112 has an optical element (not shown) configured to control the intensity and the position of the laser light L, and an attenuator (not shown) configured to attenuate the laser light L to adjust an output thereof. Also, the optical system 112 may be configured to control the split of the laser light L.

The lens 113 is configured to radiate the laser light L to the combined wafer T held by the chuck 100. The laser light L emitted from the laser radiation device 110 passes through the first wafer W and is radiated to the laser absorption layer P. The lens 113 may be configured to be movable up and down by an elevating mechanism (not shown).

In addition, an imaging mechanism 120 is provided above the chuck 100. The imaging mechanism 120 includes one or more cameras 121 selected from, for example, a macro camera and a micro camera, and a calculator 122. Further, the imaging mechanism 120 may be configured to be movable in the Y-axis direction and the Z-axis direction by an elevating mechanism (not shown) or a moving mechanism (not shown).

The camera 121 images an outer end of the combined wafer T held on the chuck 100. The camera 121 is provided with, for example, a coaxial lens, and serves to radiate infrared light (IR) and receive reflection light from an object.

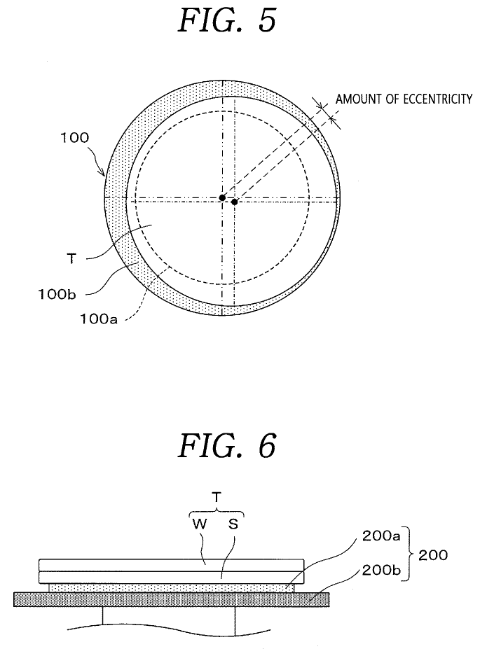

The calculator 122 detects the position of the combined wafer T on the chuck 100 from the image data obtained by the camera 121, and calculates an amount of eccentricity (amount of misalignment with respect to a horizontal direction: see FIG. 5) between the rotation center of the chuck 100 and the center of the combined wafer T based on this information. Here, the calculator 122 is independently provided in the imaging mechanism 120 in this way, but it may be included in the above-described control device 40. The imaging result from the camera 121 and the position and the amount of eccentricity of the combined wafer T calculated by the calculator 122 may be outputted to the control device 40.

Further, in FIG. 5, in order to clearly illustrate the amount of eccentricity between the rotation center of the chuck 100 and the center of the combined wafer T, the chuck 100 and the combined wafer T are shown on a scale different from an actual value. In addition, in the drawings to be referred to for other explanations, the chuck 100 and the combined wafer T may also be shown on a scale different from the actual value.

Furthermore, the positional relationship between the camera 121 of the imaging mechanism 120 and the lens 113 of the laser radiation device 110, and the positional relationship between the camera 121 of the imaging mechanism 120 and the rotation center of the chuck 100 are stored in the control device 40 in advance.

A transfer pad 130 is further provided above the chuck 100. The transfer pad 130 is configured to be movable up and down by an elevating mechanism (not shown). Further, the transfer pad 130 has an attraction surface for attracting and holding the first wafer W. The transfer pad 130 transfers the first wafer W between the chuck 100 and the transfer arm 23. Specifically, after the chuck 100 is moved to below the transfer pad 130 (a delivery position with respect to the transfer arm 23), the transfer pad 130 attracts and holds the rear surface Wb of the first wafer W, and separates it from the second wafer S. Subsequently, the separated first wafer W is handed over from the transfer pad 130 to the transfer arm 23, and taken out of the wafer processing apparatus 31.

The wafer processing apparatus 31 according to the exemplary embodiment is configured as described above. However, the configuration of the wafer processing apparatus 31 is not limited thereto.

For example, although FIG. 3 illustrates an example case where the substrate holder 100a and the light shield 100b constituting the chuck 100 are configured as one body, the substrate holder 100a and the light shield 100b may be configured as separate bodies.

In this case, as shown in FIG. 6, a chuck 200 may be prepared by stacking a substrate holder 200a of an approximately circular shape having a diameter at least smaller than that of the combined wafer T and a light shield 200b of an approximately circular shape having a diameter larger than that of the combined wafer T.

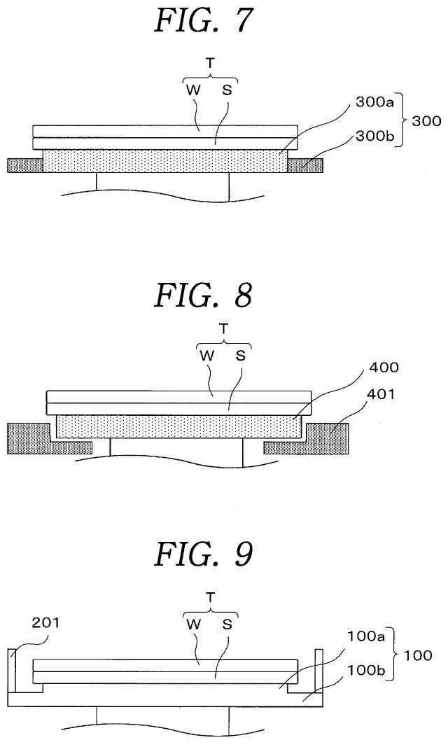

As another example, as shown in FIG. 7, a chuck 300 may be composed of a substrate holder 300a of an approximately circular shape having a diameter at least smaller than that of the combined wafer T, and a light shield 300b having an approximately annular shape and disposed to surround the substrate holder 300a.

In addition, a chuck 400 may be composed of only a substrate holder of an approximately circular shape having a diameter at least smaller than that of the combined wafer T, and a cover member 401 as the light shield having a light-shielding surface may be disposed below a substrate holding surface of the chuck 400. As an example, the cover member 401 may be disposed to surround a periphery of the chuck 400, as illustrated in FIG. 8.

Furthermore, the cover member 401 does not need to be disposed to surround the periphery of the chuck 400 along the entire circumference thereof as shown in FIG. 8, and the cover member 401 only needs to be disposed to surround at least a part of the periphery of the chuck 400 directly under the lens 113 when the radiation position of the laser light L is shifted radially outwards from an outer peripheral end of the combined wafer T.

In addition, although FIG. 3 illustrates an example case where the wafer drop prevention pin 101 is fixed to the bottom surface of the light shield 100b, the way to fix the wafer drop prevention pin 101 is not limited thereto.

Specifically, as shown in FIG. 9, for example, a wafer drop prevention pin 201 may be disposed so as to protrude upwards from a top surface of the light shield 100b. Likewise, although not illustrated, the wafer drop prevention pin 201 may be disposed so as to protrude from a top surface of the light shield 200b (300b) shown in FIG. 6 (FIG. 7), or a top surface of the cover member 401 shown in FIG. 8. Further, in the configuration where the wafer drop prevention pin 201 protrudes from the top surface of the cover member 401 in this way, it is desirable that the cover member 401 is disposed so as to surround the entire circumference of the chuck 400.

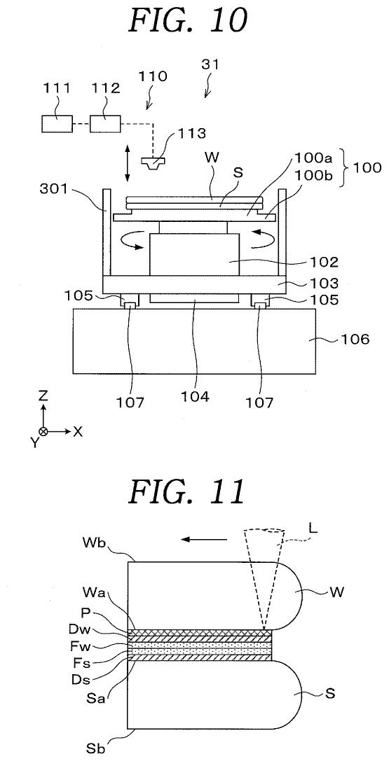

Furthermore, as shown in FIG. 10, a wafer drop prevention pin 301 may be disposed so as to protrude upwards from a top surface side of the slider table 103 instead of the light shield 100b. In this case, the wafer drop prevention pin 301 is configured to be movable in the Y-axis direction as one body with the slider table 103 by the moving mechanism 105.

Moreover, in the present exemplary embodiment, the first wafer W is separated from the second wafer S by using the transfer pad 130 of the wafer processing apparatus 31. However, in the case where the separating device (not shown) is independently disposed in the wafer processing system 1 as mentioned above, the separation of the first wafer W may be performed by using the separating device instead of the transfer pad 130. In this case, the transfer pad 130 transfers the combined wafer T to the transfer arm 23 without separating the first wafer W from the second wafer S.

Now, a wafer processing performed by using the wafer processing system 1 configured as described above will be described. In the present exemplary embodiment, the first wafer W and the second wafer S are bonded in a bonding apparatus (not shown) outside the wafer processing system 1 to form the combined wafer T in advance.

First, the cassette Ct accommodating the plurality of combined wafers T is placed on the cassette placement table 11 of the carry-in/out block 10.

Next, the combined wafer T in the cassette Ct is taken out by the wafer transfer device 22, and transferred to the wafer processing apparatus 31. In the wafer processing apparatus 31, the combined wafer T is handed over from the transfer arm 23 onto the chuck 100, and is attracted to and held by the chuck 100. Subsequently, the chuck 100 is moved to a processing position by the moving mechanism 105. This processing position is a position where laser light can be radiated from the laser radiation device 110 to the combined wafer T (laser absorption layer P).

Thereafter, as shown in FIG. 11, the laser light L (CO₂ laser light) is radiated in a pulse shape from the laser radiation device 110 to the laser absorption layer P, more specifically, to an interface between the laser absorption layer P and the first wafer W. At this time, the laser light L is radiated from the rear surface Wb side of the first wafer W, penetrates the first wafer W, and is absorbed into the laser absorption layer P. The bonding strength at the interface between the laser absorption layer P and the first wafer W is reduced by this laser light L. In the present exemplary embodiment, the expression “the bonding strength is reduced” means a state in which the bonding strength is reduced as compared to before the radiation of the laser light L at least, and includes modification of the laser absorption layer P and separation of the laser absorption layer P and the first wafer W.

A specific wafer processing method in the wafer processing apparatus 31 will be discussed.

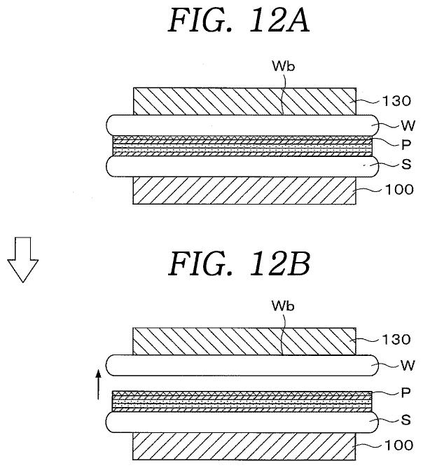

Next, the chuck 100 is moved to the delivery position by the moving mechanism 105. Then, as shown in FIG. 12A, the rear surface Wb of the first wafer W is attracted to and held by the transfer pad 130. Thereafter, as shown in FIG. 12B, while the first wafer W is being attracted and held by the transfer pad 130, the transfer pad 130 is raised to thereby separate the first wafer W from the laser absorption layer P. At this time, since the bonding strength is reduced at the interface between the laser absorption layer P and the first wafer W as a result of the radiation of the laser light L as described above, the first wafer W can be separated from the laser absorption layer P without applying a large load.

The separated first wafer W is handed over from the transfer pad 130 to the transfer arm 23 of the wafer transfer device 22, and transferred to the cassette Cw of the cassette placement table 11. Further, the first wafer W taken out from the wafer processing apparatus 31 may be transferred to the cleaning apparatus 32 before being transferred to the cassette Cw so that the front surface Wa, which is a separation surface, may be cleaned. In this case, the first wafer W taken out from the wafer processing apparatus 31 may be transferred to the cleaning apparatus 32 after its front and rear surfaces are inverted in the inverting apparatus 33 so that its front surface Wa as the separation surface faces upwards.

Meanwhile, the second wafer S held by the chuck 100 is handed over to the transfer arm 23, and is transferred to the cleaning apparatus 32. In the cleaning apparatus 32, the surface of the laser absorption layer P, which is a separation surface, is scrub-cleaned. Also, in the cleaning apparatus 32, the rear surface Sb of the second wafer S as well as the surface of the laser absorption layer P may be cleaned. In addition, a cleaning device configured to clean the surface of the laser absorption layer P and a cleaning device configured to clean the rear surface Sb of the second wafer S may be provided separately.

Afterwards, the second wafer S after being subjected to all the required processes is transferred to the cassette Cs on the cassette placement table 11 by the wafer transfer device 22. In this way, the series of processes of the wafer processing in the wafer processing system 1 are completed.

Now, a method of radiating the laser light L in the above-described wafer processing apparatus 31 will be explained.

In the present exemplary embodiment, the laser light L is radiated in a pulse shape while rotating the combined wafer T held by the chuck 100 and moving the radiation position of the laser light L from a radially outer side toward a radially inner side by moving the combined wafer T in the radial direction. At this time, if it is intended to keep constant an interval at which the laser light L is radiated in order to perform the separation of the first wafer W from the laser absorption layer P uniformly within the surface of the wafer, the rotation speed of the combined wafer T needs to be set to be high because a peripheral speed of the combined wafer T at the radiation position of the laser light L decreases as the radiation position of the laser light L is moved from the radially outer side toward the radially inner side, more specifically, as the radiation position of the laser light L approaches the rotation center of the chuck 100. If, however, the rotation speed of the combined wafer T is set to be high in this way, there is a risk that the first wafer W will be separated from the second wafer S even during the radiation of the laser light L due to a centrifugal force caused by the rotation of the combined wafer T.

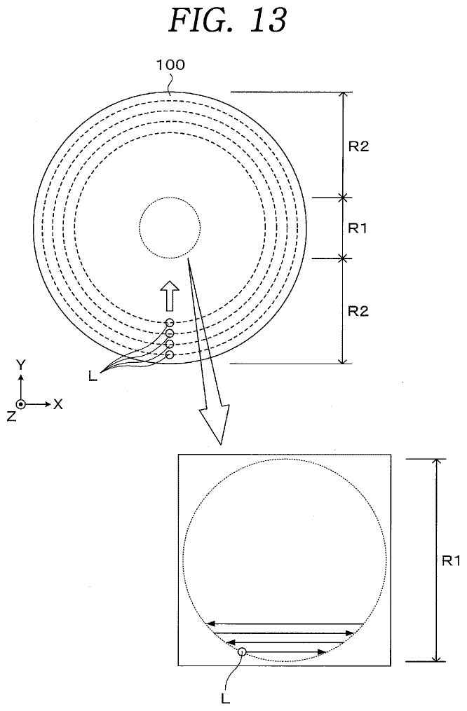

Therefore, in the present exemplary embodiment, when radiating the laser light L to an outer peripheral region R2 (see FIG. 13) of the chuck 100 where the rotation speed of the combined wafer T is relatively low, the combined wafer T is rotated, whereas when radiating the laser light L to a central region R1 (see FIG. 13) of the chuck 100 where the rotation speed of the combined wafer T is high, the laser light Lis scanned in the state that the rotation of the combined wafer T is stopped.

The central region R1 of the chuck 100 where the laser light Lis scanned is a circular region having a required length from the rotation center of the chuck 100 in the radial direction, and is set in advance prior to the wafer processing in the wafer processing device 31. The length of the central region R1 is, for example, a position in the radial direction at which the relative rotation speed of the chuck 100 with respect to the lens 113 of the laser radiation device 110 reaches an upper limit, in other words, a limit position where the laser light L does not overlap. The length of the central region R1 is, by way of example, about 10 mm.

The outer peripheral region R2 where the chuck 100 is rotated during the radiation of the laser light L is set to a region outside the central region R1.

During the wafer processing in the wafer processing apparatus 31, first, an outer end of the combined wafer T on the chuck 100 moved to the processing position is imaged by using the imaging mechanism 120. Specifically, the outer end of the combined wafer T (first wafer W) is imaged in 360 degrees in the circumferential direction by the camera 121, while rotating the chuck 100.

Subsequently, based on the imaging result by the camera 121, an amount of eccentricity (see FIG. 5) between the rotation center of the chuck 100 and the center of the combined wafer T is calculated. Specifically, the position of the outer end of the combined wafer T (first wafer W) in 360 degrees in the circumferential direction is detected from the image obtained by the camera 121, and the center position of the combined wafer T is calculated based on it. Further, as stated above, the positional relationship between the camera 121 and the chuck 100 is stored in advance in the control device 40. Therefore, by comparing the positional relationship between the camera 121 and the chuck 100 with the calculated center position of the combined wafer T, the amount of eccentricity between the rotation center of the chuck 100 and the center of the combined wafer T can be calculated.

Here, when the calculated amount of eccentricity is so large that it exceeds a predetermined threshold value, the processing in the wafer processing apparatus 31 may not be started, and the combined wafer T as a processing target may be carried out from the wafer processing apparatus 31. In this case, an operator may be notified of the stop of the processing by setting off an alarm, for example. Alternatively, when the amount of eccentricity exceeds the threshold value, the combined wafer T on the chuck 100 may be held by the transfer pad 130, and then placed on the chuck 100 again. The aforementioned threshold value, which is a criterion for stopping the wafer processing, may be set to a value at which the substrate holding surface is exposed when the chuck 100 holds the combined wafer T, for example.

Subsequently, the positions of the central region R1 and the outer peripheral region R2 of the chuck 100 are obtained, and the central region R1 and the outer peripheral region R2 are set on the combined wafer T, which is a target to which the laser light L is to be radiated. More specifically, regions corresponding to the central region R1 and the outer peripheral region R2 (regions overlapping the central region R1 and the outer peripheral region R2 when viewed from the top) are set within the surface of the combined wafer T held by the chuck 100. The positions of the central region R1 and the outer peripheral region R2 of the chuck 100 are set based on the rotation center of the chuck 100 as stated above, and those previously outputted to the control device 40 may be acquired.

Thereafter, the radiation position of the laser light L to the combined wafer T (more specifically, the laser absorption layer P) is set. The radiation position of the laser light L to the combined wafer T is set for each of the regions corresponding to the central region R1 and the outer peripheral region R2 of the chuck 100 set on the combined wafer T. That is, the radiation positions are set separately for the region where the laser light L is radiated to the combined wafer T while rotating the chuck 100 and the region where the laser light L is radiated to the combined wafer T while scanning the lens 113 in the state that the rotation of the chuck 100 is stopped.

In the following description, within the region corresponding to the outer peripheral region R2, a region radially outside the outer peripheral region R2 including a radiation start position of the laser light L may sometimes be referred to as “edge-side region R2e,” and a region radially inside the outer peripheral region R2 including a radiation end position of the laser light L may sometimes be referred to as “center-side region R2c.” The outer peripheral end of the combined wafer T and its vicinity are located in the edge-side region R2e, and the center of the combined wafer T and its vicinity are located in the center-side region R2c.

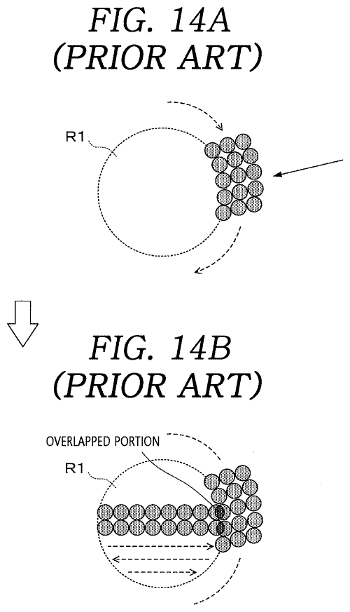

Here, if the radiation position of the laser light L for the region corresponding to the outer peripheral region R2 is determined based on the position of the outer end of the combined wafer T, the portion where the bonding strength is reduced as a result of the radiation of the laser light L may extend to the central region R1 as shown in FIG. 14A due to various factors such as a beam diameter of the laser light L or an index amount (spatial radiation interval of the laser light L).

If the bonding strength is reduced in a part of the central region R1 by the radiation of the laser light L for the purpose of reducing the bonding strength in the region corresponding to the outer peripheral region R2, the portion with the reduced bonding strength and the radiation position of the laser light L may overlap as shown in FIG. 14B when the laser light L is radiated to the region corresponding to the central region R1. As a result, the device layer Dw formed under the laser absorption layer P may be damaged.

In the wafer processing apparatus 31 according to the exemplary embodiment, however, the radiation position of the laser light L onto the combined wafer T in the region corresponding to the outer peripheral region R2 is determined based on the position of the rotation center of the chuck 100.

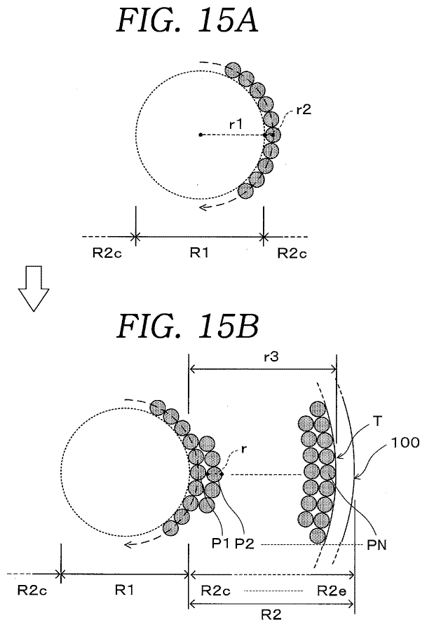

Specifically, in the present exemplary embodiment, the radiation position of the laser light L for the region corresponding to the center-side region R2c of the outer peripheral region R2 is set in consideration of the size of the central region R1 set based on the rotation center of the chuck 100 and the beam diameter of the laser light L to be radiated. More specifically, as illustrated in FIG. 15A, the rotation center of the chuck 100 is used as a reference, and a position in the radial direction obtained by adding a radius r1 of the central region R1 and a beam radius r2 of the laser light L is set as the radiation position of the laser light L. Accordingly, the portions having the reduced bonding strength due to the radiation of the laser light L are arranged in the circumferential direction along a boundary between the central region R1 and the outer peripheral region R2 in the center-side region R2c.

The radiation position of the laser light L for the edge-side region R2e of the outer peripheral region R2 is set based on a radiation position P1 (see FIG. 15B) of the laser light L on the innermost side of the center-side region R2c set as stated above. Specifically, as shown in FIG. 15B, a distance from the center-side region R2c in the radial direction of the combined wafer T is calculated from “beam diameter r of the laser light L”×“a natural number N, which is a repetition number of the radiation of the laser light L in the radial direction”, and a position PN (see FIG. 15B) where this distance becomes closest to a distance r3 from the outer end of the combined wafer T obtained from the imaging result by the camera 121 to the radiation position P1 (see FIG. 15B) of the laser light L on the innermost side of the center-side region R2c is set as the radiation start position of the laser light L in the edge-side region R2e.

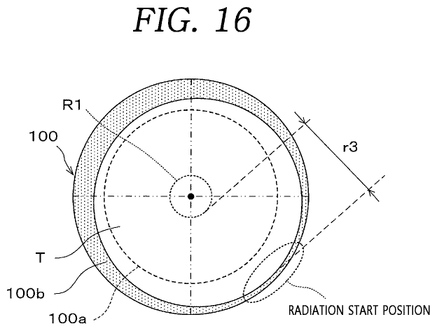

Further, when setting this radiation start position of the laser light L, the amount of eccentricity between the rotation center of the chuck 100 and the center of the combined wafer T calculated from the imaging result by the camera 121 is taken into account. That is, in consideration of the calculated amount of eccentricity, the position of the outer end of the combined wafer T farthest from the position of the rotation center of the chuck 100, which is the reference for the radiation position of the laser light L for the outer peripheral region R2, is determined as the radiation start position of the laser light L in the edge-side region R2e, as illustrated in FIG. 16.

Therefore, even when the combined wafer T is held eccentrically with respect to the chuck 100, the laser light L can be appropriately radiated to the entire surface of the combined wafer T (laser absorption layer P).

Once the radiation position of the laser light L for the region corresponding to the outer peripheral region R2 is determined, the radiation of the laser light L to the combined wafer T (laser absorption layer P) in the region corresponding to the outer peripheral region R2 is begun. At this time, the wafer processing apparatus 31 repeatedly performs the rotation of the chuck 100 (combined wafer T) by the rotating mechanism 104 and the movement of the chuck 100 (combined wafer T) in the Y-axis direction by the moving mechanism 105, while radiating the laser light L from the laser radiation device 110. Accordingly, as shown in FIG. 13, the laser light L is radiated concentrically with the chuck 100 from a radially outer side toward a radially inner side in the outer peripheral region R2. When the laser light L is radiated to the combined wafer T (laser absorption layer P), the bonding strength at the interface between the laser absorption layer P and the first wafer W is reduced.

Further, in order to improve the throughput of the wafer processing, the laser light L may be split by the aforementioned optical system 112, and multiple points on the laser absorption layer P may be irradiated with the laser light L simultaneously.

According to the present exemplary embodiment, the substrate holder 100a of the chuck 100 is formed to have a diameter at least smaller than that of the combined wafer T held by the substrate holder 100a, desirably, to have an appropriate size in consideration of the transfer accuracy of the combined wafer T. Therefore, even if the position of the outer end of the combined wafer T changes as stated above when the chuck 100 is rotated, so even if the combined wafer T is not placed directly under the radiation of the laser light L by the laser radiation device 110, the laser light L is not substantially radiated to the substrate holder 100a that holds the combined wafer T. Thus, the damage to the substrate holder 100a can be appropriately suppressed.

In this case, instead of the substrate holder 100a, the light shied 100b is exposed directly under the radiation of the laser light L by the laser radiation device 110. Accordingly, even when the combined wafer T is not placed directly under the radiation, the laser light L is radiated to the light shield 100b, and, as a result, damage to the components disposed below the chuck 100 or generation of particles due to the radiation of the laser light L can be suppressed.

Further, according to the present exemplary embodiment, the height of the top surface of the light shield 110b is set to be lower than the height of the top surface of the substrate holder 100a at least. Accordingly, even if the laser light L is radiated to the light shield 100b as described above, the laser light L is still focused on the combined wafer T on the substrate holder 110a, so that the distance from a focal position to the top surface of the light shield 100b irradiated with the laser light L increases, and, as a result, the damage to the light shield 100b and the generation of particles can be suppressed (focus shift).

Also, by adopting such a configuration in which the height of the top surface of the light shield 110b is lower than the height of the top surface of the substrate holder 100a at least in this manner, the light shield 110b is suppressed from interfering with the combined wafer T on the substrate holder 110a.

Furthermore, since the light shield 100b is disposed around the substrate holder 100a, the laser light L is suppressed from being emitted to below the chuck 100 even when the combined wafer T is not placed directly under the radiation of the laser light L. However, even when the light shield 100b is disposed in this way, the laser light L may be radiated only when the combined wafer T is placed directly under the radiation of the laser light L, and the radiation of the laser light L may be stopped when the light shield 100b is exposed directly under the radiation of the laser light L. In other words, a so-called on-off control may be performed depending on whether the combined wafer T is placed directly under the radiation of the laser light L or whether the light shield 100b is exposed. The on-off control for the radiation of the laser light L is controlled by, for example, the control device 40. By controlling the radiation of the laser light L on and off in this way, the radiation of the laser light L to the light shield 100b is reduced, and, as a result, the component life of the light shield 100b can be lengthened.

In addition, when controlling the radiation of the laser light L on and off in this manner, the determination upon whether the combined wafer T is present directly under the radiation of the laser light L, i.e., whether the light shield 100b is exposed directly under the radiation of the laser light L may be made based on the imaging result by the imaging mechanism 120 described above.

The above-described on/off control of the radiation of the laser light L may be performed not only when the light shield 100b is exposed directly under the radiation of the laser light L, but also when there is no light shield 100b directly under the radiation of the laser light L or when there is a risk that the substrate holding surface may be exposed directly under the radiation of the laser light L because the amount of eccentricity exceeds the threshold value as described above.

Upon the completion of the radiation of the laser light L to the region corresponding to the outer peripheral region R2 (reduction of the bonding strength between the first wafer W and the laser absorption layer P), the radiation of the laser light L to the combined wafer T (laser absorption layer P) in the region corresponding to the central region R1 is then started. When the laser light Lis radiated to the region corresponding to the central region R1, the rotation of the chuck 100 is stopped. Then, while radiating the laser light L in the pulse shape from the laser radiation device 110, the scanning of the radiation position of the laser light L in the X-axis direction and the movement of the chuck 100 (combined wafer T) in the Y-axis direction by the moving mechanism 105 are alternately repeated (see FIG. 13).

Further, the method of radiating the laser light L to the region corresponding to the central region R1 is not limited to the example shown in FIG. 13. As another example, when radiating the laser light L to the region corresponding to the central region R1, the rotation of the chuck 100 is stopped. Then, while radiating the laser light L from the laser radiation device 110 in the pulse shape, the radiation position of the laser light L may be moved in a spiral shape, or an annular shape that gradually becomes smaller circles as it goes from an outer peripheral region toward a center of the central region R1.

According to the present exemplary embodiment, as depicted in FIG. 15A and FIG. 15B, since the portion with the reduced bonding strength is suppressed from extending to the central region R1 when radiating the laser light L to the outer peripheral region R2, an overlap of the radiation regions of the laser light L as shown in FIG. 14B is appropriately suppressed when the laser light L is radiated to the region corresponding to the central region R1. This allows the entire surface of the first wafer W to be appropriately separated from the laser absorption layer P, and, also, suppresses the damage to the device layer Dw.

The combined wafer T in which the bonding strength is reduced in the entire surfaces of the first wafer W and the laser absorption layer P as a result of radiating the laser light L to the central region R1 and the peripheral region R2 is then moved to the delivery position by the moving mechanism 105 the chuck 100 as described above, and the first wafer W is then separated from the laser absorption layer P by the transfer pad 130 as shown in FIG. 12A and FIG. 12B.

Here, the combined wafer T in which the bonding strength between the first wafer W and the laser absorption layer P has been reduced as a result of the radiation of the laser light L is moved to the delivery position by the moving mechanism 105 in this manner. If, however, the bonding strength between the first wafer W and the laser absorption layer P is reduced in the entire surfaces thereof as stated above, an inertial force accompanying this movement may cause the first wafer W to fall from the second wafer S (laser absorption layer P).

Likewise, even during the radiation of the laser light L, a centrifugal force accompanying the rotation of the chuck 100 may cause the first wafer W to be separated from the laser absorption layer P and fall from the second wafer S.

As a resolution, in the wafer processing apparatus 31 according to the present exemplary embodiment, as illustrated in FIG. 3 and FIG. 4, the plurality of, for example, the at least three wafer drop prevention pins 101 are provided so as to surround the combined wafer T held by the substrate holder 100a. With this configuration, in the present exemplary embodiment, even if the first wafer W is separated from the laser absorption layer P due to the inertial force or the centrifugal force caused by the movement or the rotation of the chuck 100 after the laser light L is radiated to the laser absorption layer P, the first wafer W is suppressed from falling from the second wafer S.

As described above, in the wafer processing apparatus 31 according to the present exemplary embodiment, the substrate holder 100a configured to substantially hold the combined wafer T is formed to have the diameter at least smaller than that of the combined wafer T held by the substrate holder 100a, and, desirably, to have the size in consideration of the transfer accuracy of the combined wafer T.

Therefore, even if the center of the combined wafer T is deviated from the rotation center of the chuck 100 due to, for example, the transfer error, or the like, the laser light L is suppressed from being radiated onto the substrate holding surface of the substrate holder 100a.

Further, in the wafer processing apparatus 31 according to the present exemplary embodiment, the light shield 100b made of the material that is not transmissive to the laser light L is disposed so as to surround the substrate holder 100a.

This suppresses the laser light L from being radiated to below the chuck 100 even when the substrate holder 100a is made to have the diameter smaller than that of the combined wafer T as described above. Therefore, the damage to the components inside the apparatus and the generation of particles may be suppressed.

In addition, in the wafer processing method using the wafer processing apparatus according to the present exemplary embodiment, the rotation center of the chuck 100 is set as the reference for the radiation position of the laser light L to the combined wafer T (laser absorption layer P), and the radiation position of the laser light L for the edge-side region R2e including the radiation start position of the laser light L is set to the position in the radial direction where the amount of eccentricity between the center of the combined wafer T and the rotation center of the chuck 100 is the largest.

Therefore, even when the center of the combined wafer T is deviated from the rotation center of the chuck 100 due to, for example, the transfer error, or the like, the laser light L can be appropriately radiated to the entire surface of the laser absorption layer P, that is, the entire surface of the first wafer W can be appropriately separated from the laser absorption layer P.

In addition, in the wafer processing method according to the present exemplary embodiment, the radiation position of the laser light L for the center-side region R2c including the radiation end position of the laser light L for the region corresponding to the outer peripheral region R2 is set to the position in the radial direction obtained by adding the radius r1 of the central region R1 and the beam radius r2 of the laser light L based on the rotation center of the chuck 100.

This suppresses the influence of the laser light L radiated to the outer peripheral region R2 (the range in which the bonding strength is reduced) from reaching the central region R1. Also, the radiation range of the laser light L is suppressed from overlapping with the range of the reduced bonding strength when radiating the laser light L to the central region R1, so that the damage to the device layer Dw may be suppressed.

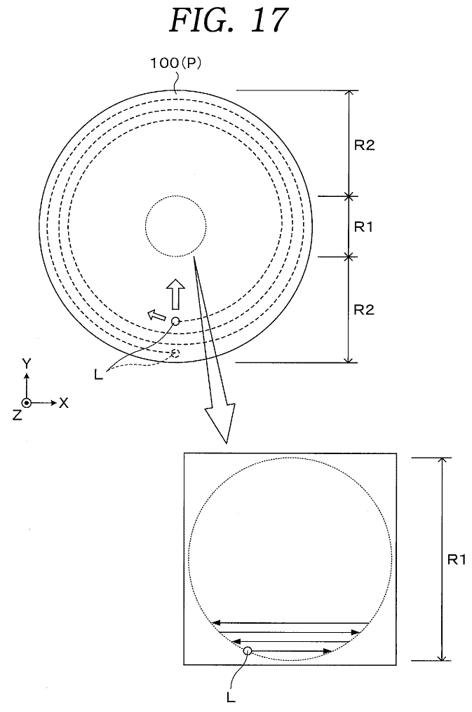

In the wafer processing method according to the above-described exemplary embodiment, the radiation positions of the laser light L for the outer peripheral region R2 are arranged concentrically in the outer peripheral region R2 as shown in FIG. 13. However, the radiation positions of the laser light L may be arranged in the spiral shape around the rotation center of the chuck 100 in the outer peripheral region R2, as depicted in FIG. 17.

In this case, when radiating the laser light L to the combined wafer T (laser absorption layer P) corresponding to the outer peripheral region R2, the chuck 100 (combined wafer T) is rotated by the rotating mechanism 104, and, also, the chuck 100 is moved in the negative Y-axis direction by the moving mechanism 105.

When the radiation positions of the laser light L are arranged in the spiral shape as stated above, the rotation and the Y-axis movement of the chuck 100 can be seamlessly controlled, so that the throughput of the radiation of the laser light L may be improved.

Alternatively, the radiation positions of the laser light L for the region corresponding to the outer peripheral region R2 may be arranged in a combination of the concentric arrangement and the spiral arrangement.

Specifically, if the radiation positions of the laser light L are arranged in the spiral shape in the entire surface of the outer peripheral region R2, the radiation positions of the laser light L in the center-side region R2c may not be distributed in the circumferential direction along the boundary between the central region R1 and the outer peripheral region R2. That is, there is a risk that the central region R1 may not have a constant circle shape as shown in FIG. 13.

As a resolution, in the wafer processing apparatus 31 according to the exemplary embodiment, the radiation positions of the laser light L may be arranged concentrically at least in the innermost area of the center-side region R2c adjacent to the boundary between the central region R1 and the outer peripheral region R2, and the radiation positions of the laser light L may be arranged in the spiral shape radially outside this innermost area. Therefore, it is possible to improve the throughput of the radiation of the laser light L to the region corresponding to the outer peripheral region R2, while controlling the setting shape of the central region R1 constant.

In this way, when the radiation positions of the laser light L are arranged in the combination of the concentric arrangement and the spiral arrangement as described above, the radiation of the laser light L to the region of the concentric arrangement and the radiation of the laser light L to the region of the spiral arrangement may be performed separately or continuously.

In addition, in the wafer processing method according to the above-described exemplary embodiment, the laser light L is sequentially radiated to the outer peripheral region R2 from the radially outer side toward the radially inner side, as shown in FIG. 13. However, the radiation of the laser light L to the outer peripheral region R2 may be performed from the radially inner side toward the radially outer side thereof.

In this case, the edge-side region R2e includes the radiation end position of the laser light L, and the center-side region R2c includes the radiation start position of the laser light L. Even in this case, the series of processes of the wafer processing in the wafer processing apparatus 31 can be performed in the same manner as in the above-described exemplary embodiment.

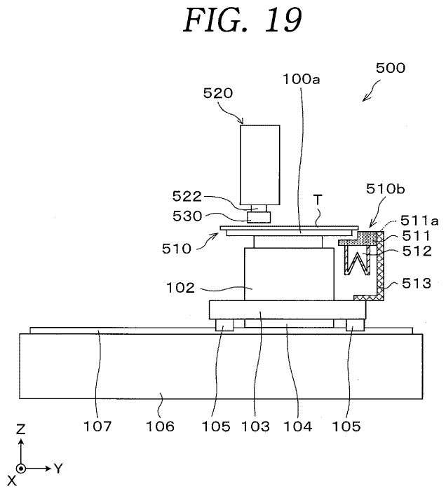

Now, as a modification example of the above-described wafer processing apparatus 31, a schematic configuration of a wafer processing apparatus 500 according to a second exemplary embodiment will be explained. In the wafer processing apparatus 500, components that are substantially identical to those of the wafer processing apparatus 31 will be assigned the same reference numerals, and detailed description thereof will be omitted. In addition, in order to avoid complication of illustrations, the illustration of the imaging mechanism 120 and the transfer pad 130 provided above a chuck is omitted in FIG. 19.

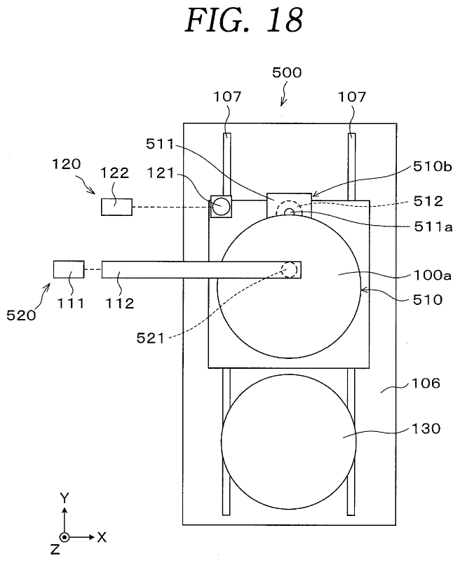

As depicted in FIG. 18 and FIG. 19, the wafer processing apparatus 500 has a chuck 510 configured to hold the combined wafer T on a top surface thereof. The chuck 510 has a substrate holder 100a and a light shield 510b. As illustrated in FIG. 19, the light shield 510b is provided on the slider table 103 with, for example, a supporting member 513 therebetween, and is configured to be movable in the Y-axis direction as one body with the chuck 510. The light shield 510b has a cover member 511 and a beam damper 512.

The cover member 511 is disposed below a lens 521 to be described later, at least when the radiation position of the laser light L is displaced from the chuck 510 during the radiation of the laser light L from a laser radiation device 520 to be described later. The height of a top surface of the cover member 511 is set to be approximately the same as or lower than the height of a top surface of the substrate holder 100a. The cover member 511 is made of a material, such as ceramic or a metal material, that is not transmissive to the laser light L from the laser radiation device 520.

Further, the cover member 511 is provided with a through hole 511a formed in a thickness direction thereof. The through hole 511a is provided at a position where it overlaps an outer edge position of the combined wafer T (first wafer W) held by the chuck 510 and is exposed from the combined wafer T (first wafer W) when viewed from the top. Therefore, when the laser radiation position is shifted from the combined wafer T (first wafer W), the through hole 511a is located directly under the radiation of the laser light L from the laser radiation device 520. The through hole 511a communicates with an internal space of the beam damper 512, that is, the laser light L from the laser radiation device 520 passes through the through hole 511a of the cover member 511 and is radiated to the inside of the beam damper 512.

The beam damper 512 has an approximately cylindrical box shape with its top surface opened through the through hole 511a. As described above, the laser light L from the laser radiation device 520 is radiated to the inside of the beam damper 512. The beam damper 512 is made of a material having beam resistance and capable of absorbing the laser light L or diffusing it in different directions, for example, a metal material such as aluminum.

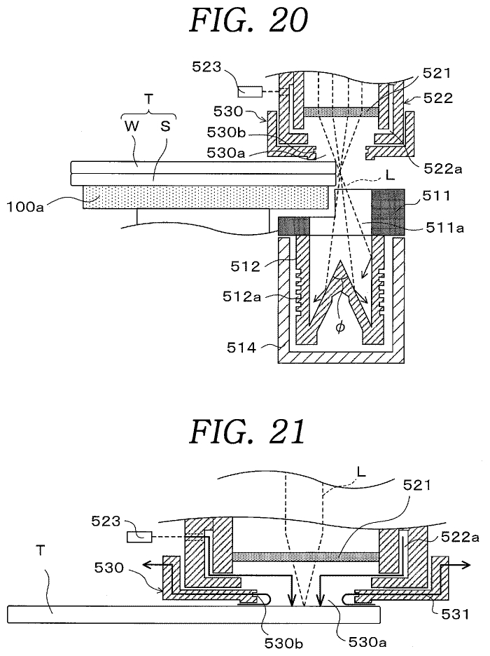

A bottom surface of the beam damper 512 has a substantially conical shape that projects upwards, as shown in FIG. 20, for example. An apex angle ¢ of this cone is desirably less than 90°. With this configuration, in the beam damper 512, the laser light L that has reached the inside of the beam damper 512 through the through hole 511a is reflected downwards or absorbed (converted into heat), as illustrated in FIG. 20, thereby being suppressed from being radiated upwards again through the through hole 511a.

In this way, the temperature of the beam damper 512 increases as the beam damper 512 absorbs the laser light L. For this reason, it is desirable to form an irregularity 512a as a cooling device on at least an outer surface (for example, an outer side surface or an outer bottom surface) of the beam damper 512 to accelerate heat dissipation (cooling of the beam damper 512) by increasing a surface area, as shown in FIG. 20. In addition, a cooling mechanism 514 (for example, a water-cooling jacket or a fan) as the cooling device configured to accelerate the heat dissipation (cooling of the beam damper 512) may be further provided outside the beam damper 512. In one example, the cooling mechanism 514 forms a coolant flow path at the outside of the beam damper 512.

In the wafer processing apparatus 500, the laser light L from the laser radiation device 520 is received and absorbed by the beam damper 512 in this manner, so that the laser light L is suppressed from reaching a place below the chuck 510.

Furthermore, in the wafer processing apparatus 500, as the laser light L is received by the beam damper 512 in this way, it is possible to suppress the laser light L from being reflected upwards to cause the damage to the members inside the apparatus, and it is also possible to suppress the generation of particles that might be caused by the radiation of the laser light L to the cover member 511.

The configuration and the shape of the beam damper 512 are not limited to the above-described examples. In the present disclosure, a beam damper is defined as a device that receives the laser light, thus having a function of suppressing damage to the members inside the apparatus due to reflection of the laser light as well as suppressing generation of particles that might be caused by the radiation of the laser light to the cover member, as described above.

The laser radiation device 520 is provided above the chuck 510. The laser radiation device 520 has the laser head 111 having therein the laser oscillator (not shown) configured to oscillate the laser light, and the optical system 112. The laser radiation device 520 also has a lens 521 and a gas supply 522. The lens 521 and the gas supply 522 are configured to be movable up and down with respect to a dust collector 530 to be described later.

The lens 521 focuses and radiates the laser light L oscillated from the laser oscillator of the laser head 111 to the combined wafer T.

The gas supply 522 has a supply path 522a formed to surround the lens 521 in a circumferential direction. The gas supply 522 supplies dry air from an air supply 523 toward a space below the lens 521 through the supply path 522a, thereby protecting the lens 521 from the particles generated during the laser processing.

As shown in FIG. 20, the wafer processing apparatus 500 has the dust collector 530 configured to collect the particles generated in the laser processing. The dust collector 530 is formed so as to surround the gas supply 522 in the circumferential direction. As shown in FIG. 21, the dust collector 530 collects the particles through a dust collection path 531. The dust collection path 531 is formed inside the dust collector 530, and the particles are collected through a plurality of suction openings 530b formed in portions of the dust collector 530 facing an opening 530a to be described later. The collected particles are connected to a non-illustrated exhaust port.

In addition, the dust collector 530 is provided with the opening 530a for allowing the laser light L from the laser radiation device 520 to pass therethrough. The opening 530a is provided directly under the radiation of the laser light L. When the laser light L is radiated from the laser radiation device 520, the opening 530a is provided at a position corresponding to the through hole 511a of the cover member 511 described above, that is, at a position overlapping the through hole 511a when viewed from the top when the laser radiation position is shifted out of the combined wafer T (first wafer W).

Here, in the wafer processing apparatus 500 according to the second exemplary embodiment, if the beam damper 512 is disposed directly under the lens 521 of the laser radiation device 520 at least, the damage to the members inside the apparatus or the generation of particles that might be caused by the radiation of the laser light L can be suppressed. If, however, only the beam damper 512 is disposed directly under the lens 521 in this way and the cover member 511 is not disposed, a space formed outside the outer end of (radially outside of) the combined wafer T below the dust collector 530 becomes larger, as compared to the case where the cover member 511 is disposed. In other words, a difference between an outer gap formed between the lower end of the dust collector 530 and the top surface of the beam damper 512 directly under the dust collector 530 and an inner gap formed between the lower end of the dust collector 530 and the top surface of the combined wafer T becomes larger than a difference between the outer gap and the inner gap formed between the lower end of the dust collector 530 and the top surface of the cover member 511 in the case where the cover member 511 is provided. If the difference between the outer gap and the inner gap enlarges in this way, a suction amount by the dust collector 530 from the inner gap side and a suction amount from the outer gap side become non-uniform. More specifically, the suction amount from the outer gap side becomes larger, making it difficult to properly collect the particles.

In view of this, it is desirable to provide not only the beam damper 512 but also the cover member 511 below the laser radiation device 520. In other words, in view of the foregoing, the cover member 511 has a function of reducing the outer gap (the distance between the dust collector 530 and the top surface of the cover member 511) formed between the dust collector 530 and the cover member 511, and, also, a function of reducing the difference between the outer gap and the inner gap (the distance between the dust collector 530 and the top surface of the combined wafer T). By reducing the difference between the outer gap and the inner gap in this way, desirably, by allowing them to have approximately the same size, the suction amount by the dust collector 530 becomes uniform, so that the collection of particles can be performed efficiently. Also, in this case, the light shield 510b may be configured to be movable up and down by, for example, a non-illustrated elevating mechanism. In this case, the size of the outer gap between the top surface of the cover member 511 and the lower end of the dust collector 530 becomes adjustable.

The wafer processing apparatus 500 according to the second exemplary embodiment is configured as described above.

In the above-described exemplar embodiments, the wafer processing method of the present disclosure is applied when performing the laser lift-off to separate the first wafer W from the laser absorption layer P. However, the wafer processing to which the wafer processing method of the present disclosure is not limited thereto.

In a manufacturing process for a semiconductor device, laser light is radiated to an inside of a silicon substrate of a wafer having a plurality of devices such as electronic circuits formed on a front surface thereof along a plane direction of the wafer to thereby form a modification layer, and the wafer is thinned by being separated starting from this modification layer. YAG laser light is used as this laser light. The laser light radiation method of the present disclosure can also be applied to form this modification layer serving as a starting point for thinning the wafer in this way. Furthermore, the laser light radiation method of the present disclosure is also applicable to a technique of modifying or flattening the front surface of the wafer and a technique of annealing the wafer.

Further, although the above exemplary embodiments have been described for the example where the radiation shape of the laser light L is circular as shown in FIG. 15A and FIG. 15B, the radiation shape of the laser light L is not limited thereto and may be controlled to any of various shapes (for example, a rectangular, etc.). As an example, the radiation shape of the laser light L can be controlled by a diffractive optical device such as a DOE (Diffractive Optical Element).

In addition, in the above-described exemplary embodiments, the scanning of the radiation position of the laser light L for the combined wafer T is performed by moving the laser radiation device and the chuck relative to each other in the horizontal direction. Instead of this, however, the radiated laser light L may be made scannable to the combined wafer T by using, for example, a galvano mirror, or the like.

Moreover, in the above-described exemplary embodiments, by setting the radiation position of the laser light L for the region corresponding to the outer peripheral region R2 based on the rotation center of the chuck 100 as a reference, an overlap of the radiation range of the laser light L in the central region R1 is suppressed. However, even if the radiation range of the laser light L is overlapped, if it is within a range that does not damage the device layer Dw, for example, if the overlapped portion is an outer periphery of a radiation spot (beam diameter) with a small amount of energy, damage to the device layer Dw can still be suppressed.

Here, it should be noted that the above-described exemplary embodiments are illustrative in all aspects and are not anyway limiting. The above-described exemplary embodiments may be omitted, replaced and modified in various ways without departing from the scope and the spirit of claims.

### EXPLANATION OF CODES

31: Wafer processing apparatus
100: Chuck
100a: Substrate holder
100b: Light shield
104: Rotating mechanism
110: Laser radiating device
L: Laser light
T: Combined wafer
W: First wafer
S: Second wafer

1. A substrate processing apparatus of processing a substrate, comprising:
a substrate holder having a holding surface on which the substrate is held;
a rotator configured to rotate the substrate on the holding surface around a rotation axis of the substrate holder;
a laser radiator configured to radiate laser light to the substrate on the holding surface; and
a light shield configured to receive the laser light from the laser radiator at a position surrounding a part of a periphery of the substrate holder or an entire periphery of the substrate holder.

2-23. (canceled)

24. The substrate processing apparatus of claim 1, wherein
the light shield is formed as one body with the substrate holder so as to surround the periphery of the substrate holder, and
a top surface of the light shield is located at a position lower than a top surface of the substrate holder.

25. The substrate processing apparatus of claim 1, wherein
the light shield is disposed around the substrate holder independently of the substrate holder, and
a top surface of the light shield is located at a position lower than a top surface of the substrate holder.

26. The substrate processing apparatus of claim 1, wherein the light shield comprises:
a cover member provided with a through hole; and
a beam damper having an internal space communicating with the through hole.

27. The substrate processing apparatus of claim 26, wherein
the beam damper is formed in a cone shape with a bottom surface projecting upwards, and
an apex angle of the cone shape is less than 90°.

28. The substrate processing apparatus of claim 26, wherein
the laser radiator comprises a gas supply configured to supply a gas,
the substrate processing apparatus further comprises a dust collector configured to collect a particle,
the dust collector is provided with an opening formed directly under radiation of the laser light, and
the through hole is disposed so as to overlap the opening in a plan view.

29. The substrate processing apparatus of claim 1, further comprising multiple substrate drop prevention pins disposed to surround the periphery of the substrate holder,
wherein the substrate drop prevention pins are formed as one body with the light shield.

30. The substrate processing apparatus of claim 1, further comprising:
a stage configured to allow the substrate holder to move in a horizontal direction; and
multiple substrate drop prevention pins disposed to surround the periphery of the substrate holder,
wherein the substrate drop prevention pins are formed as one body with the stage.

31. The substrate processing apparatus of claim 1, further comprising:
circuitry configured to perform:
setting, on the substrate, a central region where the laser light is radiated while being scanned and an outer peripheral region radially outside the central region, the central region and the outer peripheral region being set with respect to the rotation axis; and
setting a position considering a radius of the central region and a beam diameter of the laser light as a radiation position of the laser light for a center-side region on a radially inner side in the outer peripheral region.

32. The substrate processing apparatus of claim 31, wherein the circuitry is configured to perform setting a radiation position of the laser light for an edge-side region on a radially outer side in the outer peripheral region based on the radiation position of the laser light for the center-side region.

33. The substrate processing apparatus of claim 32, further comprising a camera configured to detect an outer end of the substrate,
wherein the circuitry is configured to perform:
calculating an amount of eccentricity between a center of the substrate and the rotation axis of the substrate holder based on information detected by the camera; and
setting the radiation position of the laser light for the edge-side region to include at least a position where the amount of eccentricity is the largest.

34. The substrate processing apparatus of claim 33, wherein in the setting of the radiation position of the laser light for the edge-side region, the circuitry is configured to perform:
calculating a distance in a radial direction of the substrate from the center-side region based on the beam diameter of the laser light and a repetition number of radiation of the laser light; and
setting, as a radiation start position of the laser light for the edge-side region, a position where the distance becomes the closest to a distance from a position of the outer end of the substrate detected by the camera to the center-side region.

35. The substrate processing apparatus of claim 34, wherein the circuitry is configured to perform setting a radiation position of the laser light for the outer peripheral region with respect to the rotation axis.

36. The substrate processing apparatus of claim 33, wherein the circuitry is configured to perform not starting radiation of the laser light to the substrate when it is determined that the amount of eccentricity between the center of the substrate and the rotation axis of the substrate holder, which is calculated based on the information detected by the camera, exceeds a preset threshold value.

37. The substrate processing apparatus of claim 33, wherein the circuitry is configured to perform repositioning the substrate on the substrate holder when it is determined that the amount of eccentricity between the center of the substrate and the rotation axis of the substrate holder, which is calculated based on the information detected by the camera, exceeds a preset threshold value.

38. The substrate processing apparatus of claim 31, wherein the circuitry is configured to perform:
radiating the laser light from the laser radiator when the substrate is placed directly under radiation of the laser light; and
stopping the radiating of the laser light from the laser radiator when the substrate holder is exposed directly under the radiation of the laser light.

39. A substrate processing method performed in a substrate processing apparatus including a substrate holder having a holding surface on which a substrate is held; a rotator configured to rotate the substrate on the holding surface around a rotation axis of the substrate holder; a laser radiator configured to radiate laser light to the substrate on the holding surface; and a light shield configured to receive the laser light from the laser radiator at a position surrounding a part of a periphery of the substrate holder or an entire periphery of the substrate holder, the substrate processing method comprising:
setting, on the substrate, a central region where the laser light is radiated while being scanned and an outer peripheral region radially outside the central region, the central region and the outer peripheral region being set with respect to the rotation axis;
setting a position considering a radius of the central region and a beam diameter of the laser light as a radiation position of the laser light for a center-side region on a radially inner side in the outer peripheral region;
setting a radiation position of the laser light for an edge-side region on a radially outer side in the outer peripheral region based on the radiation position of the laser light for the center-side region; and
receiving, by the light shield, the laser light passing through a radially outside of the substrate.

40. The substrate processing method of claim 39, wherein the light shield is disposed lower than a top surface of the substrate holder.

41. The substrate processing method of claim 39, further comprising detecting an amount of eccentricity between a center of the substrate and the rotation axis of the substrate holder,
wherein the radiation position of the laser light for the edge-side region is set to include at least a position where the amount of eccentricity is the largest.

42. The substrate processing method of claim 41, further comprising:
in the setting of the radiation position of the laser light for the edge-side region,
calculating a distance in a radial direction of the substrate from the center-side region based on a beam diameter of the laser light and a repetition number of radiation of the laser light; and
setting, as a radiation start position of the laser light for the edge-side region, a position where the distance becomes the closest to a distance from a position of an outer end of the substrate detected by a camera to the center-side region.

43. The substrate processing method of claim 41, wherein radiation of the laser light to the substrate is not started when it is determined that the detected amount of eccentricity exceeds a preset threshold value.

44. The substrate processing method of claim 39, wherein
the laser light is radiated from the laser radiator when the substrate is placed directly under radiation of the laser light, and
the radiation of the laser light is stopped from the laser radiator when the substrate holder is exposed directly under the radiation of the laser light.
